(19) United States
(12) Patent Application Publication
(10) Pub. No.: US 2012/0235121 A1
(43) Pub. Date: Sep. 20, 2012

(54) ORGANIC LIGHT EMITTING DEVICE AND METHOD FOR FORMING THE SAME

(75) Inventors: Chien-Chih CHEN, Taichung County (TW); Ching-Chiun WANG, Miaoli County (TW); Chih-Yung HUANG, Taichung County (TW); Jwo-Huei JOU, Taipei City (TW); Fu-Ching TUNG, Hsinchu City (TW)

(73) Assignee: INDUSTRIAL TECHNOLOGY RESEARCH INSTITUTE, Hsinchu (TW)

(21) Appl. No.: 13/236,502

(22) Filed: Sep. 19, 2011

(30) Foreign Application Priority Data
Mar. 14, 2011 (TW) TW100108471

(51) Int. Cl. H01L 51/52; H01L 51/56

(52) U.S. Cl. 257/40; 438/46; 257/E51.018; 257/E51.001

(57) ABSTRACT

According to an embodiment of the disclosure, an organic light emitting device is provided, which includes: an inflexible tube comprising an external surface and an internal surface; a transparent conductive layer on the internal surface of the inflexible tube; an organic light emitting layer disposed in the inflexible tube and on the transparent conductive layer; and a conductive layer disposed in the inflexible tube and on the organic light emitting layer. According to an embodiment of the disclosure, a method for forming an organic light emitting device is also provided.

### CROSS REFERENCE TO RELATED APPLICATIONS

This Application claims priority of Taiwan Patent Application No. 100108471, filed on Mar. 14, 2011, the entirety of which is incorporated by reference herein.

### BACKGROUND

1. Technical Field

The present disclosure relates to a light emitting device, and in particular relates to an organic light emitting device.

2. Description of the Related Art

For present illuminating devices, fluorescent tubes are usually used to provide needed illumination. Argon or a mixed gas of argon and neon in low pressure, and a mercury vapor are usually sealed in the fluorescent tube. Filament coils made of tungsten are assembled at two ends of the tube. After connecting power, a temperature of the filaments rises and electrons are released, such that gas in the tube is transformed into plasma. After a voltage between the filaments exceeds a fixed value, the mercury vapor radiates ultraviolet light. A fluorescent paint made of phosphor coated on an internal surface of the fluorescent tube can absorb ultraviolet light, and then release visible light with longer wavelengths for illumination.

However, the mercury vapor used in the fluorescent tube causes environment pollution, and if the fluorescent tube is broken, the mercury vapor may be harmful for human health. Furthermore, the ultraviolet light may partially leak, which is also harmful for human health.

Thus, illumination device is needed which is more safe, environmentally friendly, and economical.

### BRIEF SUMMARY

An embodiment of the disclosure provides an organic light emitting device which includes: an inflexible tube comprising an external surface and an internal surface; a transparent conductive layer on the internal surface of the inflexible tube; an organic light emitting layer disposed in the inflexible tube and on the transparent conductive layer; and a conductive layer disposed in the inflexible tube and on the organic light emitting layer.

An embodiment of the disclosure provides a method for forming an organic light emitting device, which includes: providing a tube body comprising an external surface and an internal surface; forming a transparent conductive layer on the internal surface of the tube body; providing an organic light emitting material source in the tube body; evaporating or depositing an organic light emitting layer on the transparent conductive layer by using the organic light emitting material source; and forming a conductive layer on the organic light emitting layer in the tube body.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 is a perspective drawing of a light emitting device according to an embodiment of the present disclosure;

FIG. 2A is a perspective drawing of a light emitting device according to an embodiment of the present disclosure;

FIG. 2B is a cross-sectional view of a light emitting device according to an embodiment of the present disclosure;

FIGS. 3A-3B are cross-sectional views of a process of a light emitting device according to an embodiment of the present disclosure;

FIGS. 4A-4B are cross-sectional views of a process of a light emitting device according to one embodiment of the present disclosure; and

FIG. 5 is a cross-sectional view of the structure of FIG. 4A in another direction (i.e. longitudinal direction).

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

The manufacturing method and method for use of the embodiment of the disclosure are illustrated in detail as follows with figures. It is understood, that the following disclosure provides many different embodiments, or examples, for implementing different features of the disclosure. Specific examples of components and arrangements are described below to simplify the present disclosure. These are, of course, merely examples and are not intended to limit the present disclosure. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers. In the figures, shapes or thicknesses of embodiments may be exaggerated for the sake of illustration clarity. Furthermore, elements not depicted or described in the figures may be of any configuration known in the art.

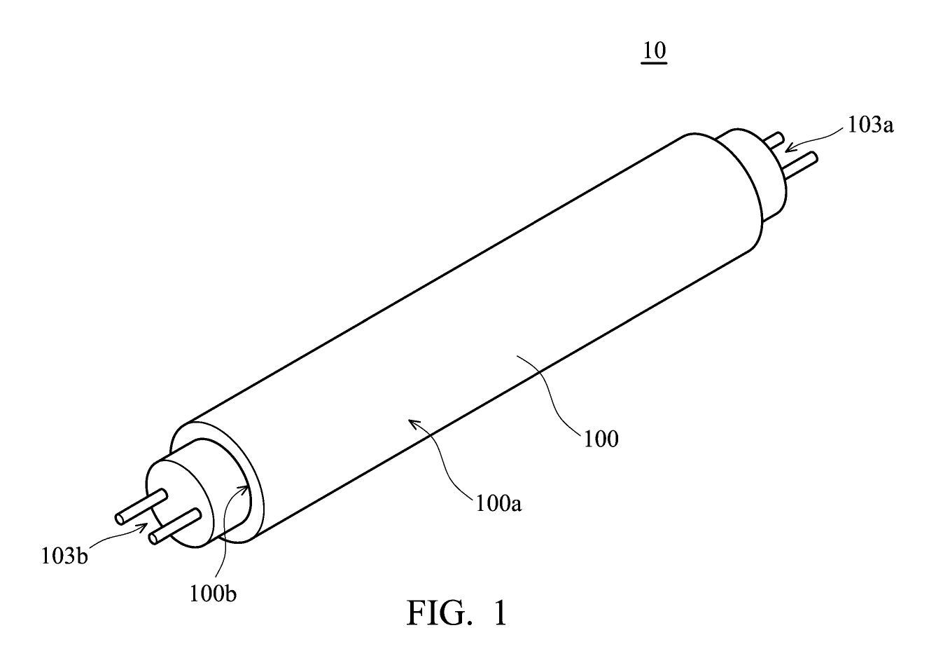

FIG. 1 is a perspective drawing of a light emitting device 10 according to an embodiment of the present disclosure. In one embodiment, the light emitting device 10 includes a tube body 100 including external surfaces 100a and 100b. Electrodes 103a and 103b are assembled at two ends of the tube body 100. A current may enter the tube body 100 through the electrodes 103a and 103b such that a light emitting layer in the tube body 100 emits light. The tube body 100 includes an inflexible tube, such as a rigid tube, which is usually formed of a transparent material. For example, in one embodiment, the material of the tube body 100 includes, for example, but is not limited to, glass, inflexible transparent polymers, or quartz. The light emitting device 10 of embodiments of the present disclosure may replace conventional lamp tubes to be assembled in conventional lamp holders. Thus, the tube body 100 is preferably an inflexible tube with a pre-determined flexural strength so as to avoid breakage during operation and/or assembly. The term “inflexible tube” here means a tube body which does not deform easily when external force is placed thereon, such as the force of taking the tube body or assembling the tube body to the lamp holders. For example, in one embodiment, the tube body 100 has a flexural strength larger than about 200 Kg/cm². In another embodiments, the tube body 100 has a flexural strength ranging from about 200 Kg/cm² to 1300 Kg/cm². In still another embodiments, the tube body 100 has a flexural strength ranging from about 300 Kg/cm² to 2500 Kg/cm². In one embodiment, the tube body 100 has a flexural strength which is substantially the same as the tube bodies of the mercury vapor type fluorescent tubes, such as glass tubes.

Also, it should be noted that, although an inflexible tube is preferably used as the tube body 100 of the embodiments of the present disclosure to be assembled in the existing lamp holders directly, the embodiments of the present disclosure is not limited thereto. In other embodiments, a flexible tube may serve as the tube body 100. For example, the tube body 100 may be formed of a transparent polymer material.

The light emitting device 10 of the embodiments of the present disclosure has a shape which is substantially similar to existing lamp tubes or lamp bulbs. Thus, the light emitting device 10 of the embodiments of the present disclosure may directly replace the existing lamp tube for illumination without need to redesign lamp holders or other equipments. The light emitting device 10 of the embodiments of the present disclosure may easily be assembled onto the existing lamp holder. For example, the tube body 100 may include, but is not limited to, a cylindrical tube (as shown in FIG. 1), a spiral tube, a spherical tube, an elliptical tube, a tapered tube, a rectangular tube, or combinations thereof. If the tube body 100 is a cylindrical tube (as shown in FIG. 1), a spiral tube, a spherical tube, an elliptical tube, a tapered tube, or combinations thereof, the internal surface 100b of the tube body 100 is a nonplanar curved surface. Housings of any lamp tube or lamp bulb may serve as the tube body 100 of the embodiments of the present disclosure.

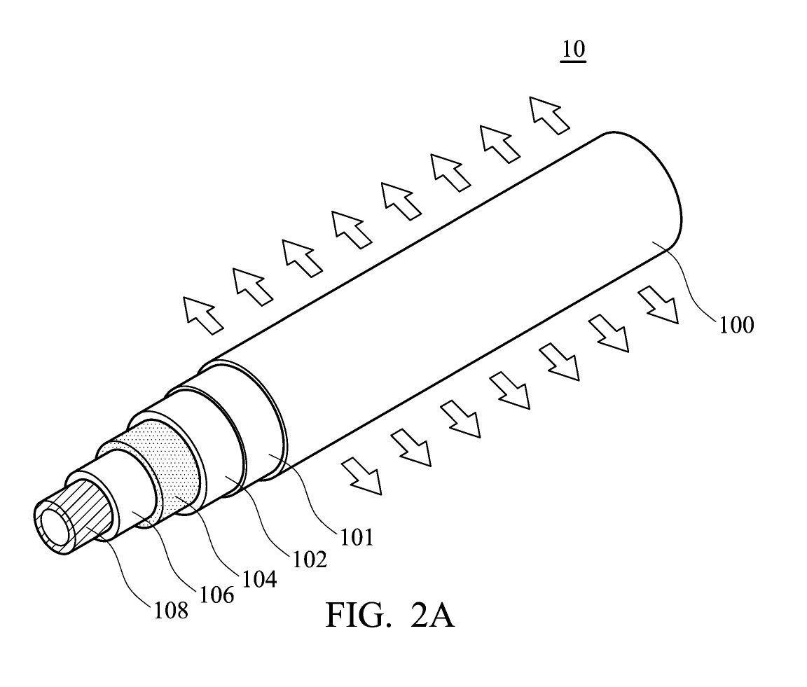

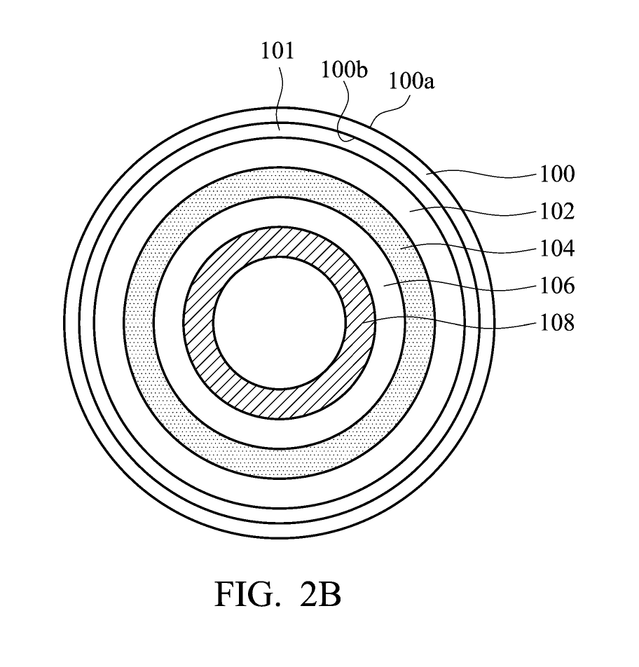

FIG. 2A is a perspective drawing of a light emitting device 10 according to an embodiment of the present disclosure, and shows each material layer included by? the tube body 100. It should be noted that, FIG. 2A is merely a schematic diagram to illustrate the relationship of each material layer. In fact, the material layers on the left side of the light emitting device 10 may be substantially aligned to one another. FIG. 2B is a cross-sectional view of a light emitting device 10 according to an embodiment of the present disclosure. In FIGS. 2A and 2B, the same or similar reference numbers are used to designate the same or similar elements.

As shown in FIGS. 2A and 2B, a transparent conductive layer 101, an organic light emitting layer 104, and a conductive layer 108 may be sequentially disposed on the internal surface 100b of the tube body 100. The material of the transparent conductive layer 101 may include, for example, but is not limited to, indium tin oxide (ITO), indium zinc oxide (IZO), indium germanium oxide (IGO), the like, or combinations thereof. The organic light emitting layer 104 may include, for example, small molecular organic light emitting materials and/or polymer light emitting materials. The material of the organic light emitting layer 104 may include any suitable organic light emitting material, for example, but is not limited to, Rubrene, C-545T, MDP3FL, TPBi, tris-(8-hydroxy quinolinol)aluminum (Alq3), poly[(2-methoxy-5-(2-ethyl hexyloxy)-1,4-phenylene vinylene] (MEH-PPV), the like, or combinations thereof. The material of the conductive layer 108 may include, for example, but is not limited to, aluminum, copper, gold, silver, the like, or combinations thereof. Alternatively, the conductive layer 108 may be formed of conductive polymer materials and/or conductive ceramic materials. In one embodiment, the transparent conductive layer 101 may substantially fully cover the internal surface 100b of the tube body 100, and the organic light emitting layer 104 may substantially fully cover the transparent conductive layer 101.

Referring to FIGS. 1, 2A, and 2B, the transparent conductive layer 101 and the conductive layer 108 may electrically connect the electrodes 103a and 103b respectively. The light emitting device 10 may have a shape and a size which is substantially the same as the existing lamp tubes or existing lamp bulbs, so the light emitting device 10 may be assembled in the existing lamp holder directly. Current may enter the organic light emitting layer 104 through the electrode 103a and 103b, the transparent conductive layer 101, and the conductive layer 108, such that the organic light emitting layer 104 emits light, as shown by arrows in FIG. 2A.

As shown in FIGS. 2A and 2B, in one embodiment, a carrier transport layer 102 may be optionally disposed between the transparent conductive layer 101 and the organic light emitting layer 104 for auxiliary transportation of carriers. For example, in one embodiment, the carrier transport layer 102 may be a hole transport layer, and the material thereof is substantially the same as conventional hole transport layers. Also, in one embodiment, a carrier transport layer 106 may be optionally disposed between the conductive layer 108 and the organic light emitting layer 104 for auxiliary transportation of carriers. For example, in one embodiment, the carrier transport layer 106 may be an electron transport layer, and the material thereof is substantially the same as conventional electron transport layers. Furthermore, in one embodiment, the organic light emitting layer 104 may include a stacking structure having a plurality of light emitting layers. Carrier transport layers may be interposed between the light emitting layers. The stacking structure having the light emitting layers may emit light with a large brightness.

In the following descriptions, the method of forming the light emitting device of the embodiments of the present disclosure is illustrated with figures, wherein the same or similar reference numbers are used to represent the same or similar elements.

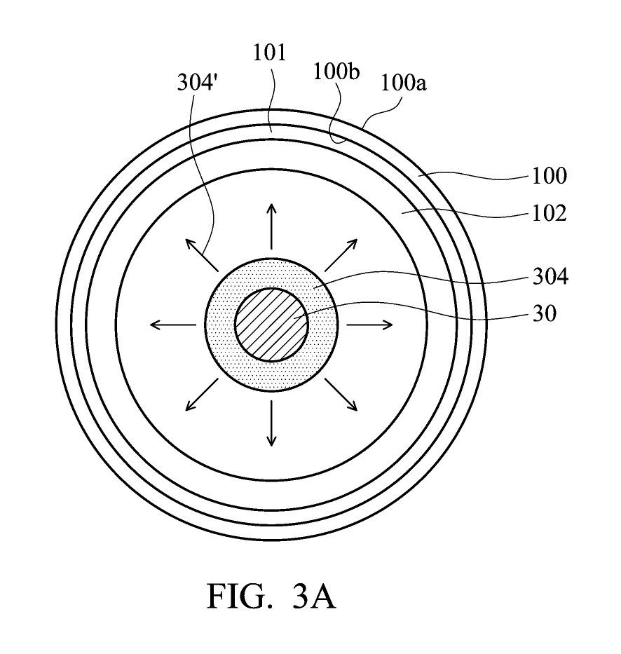

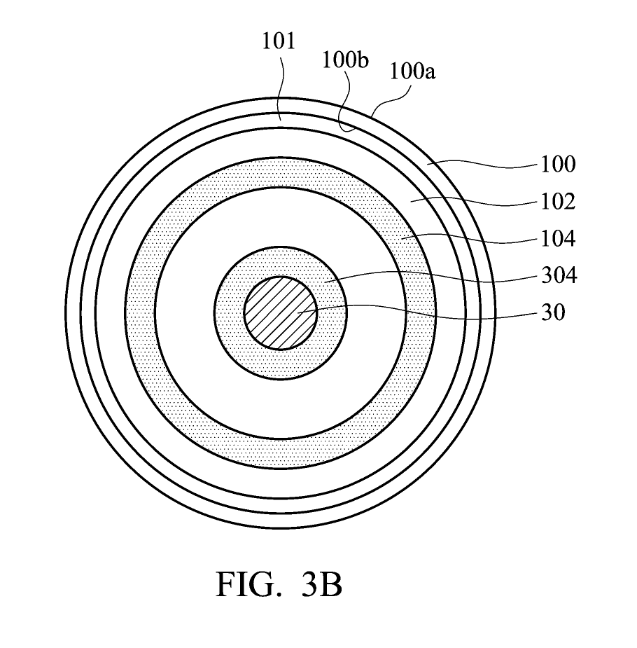

FIGS. 3A-3B are cross-sectional views of a process of a light emitting device according to an embodiment of the present disclosure. As shown in FIG. 3A, a tube body 100 is provided firstly, wherein the tube body 100 includes an external surface 100a and an internal surface 100b. A transparent conductive layer 101 is formed on the internal surface 100b of the tube body 100. The forming method of the transparent conductive layer 101 is, for example, by chemical vapor deposition, sputtering, spin coating, or other suitable methods. For example, in one embodiment, an ITO powder is dissolved in a solvent, and then the solvent dissolved with the ITO powder is spin coated onto the internal surface 100b of the tube body 100 (e.g., by directly rotating the tube body 100 rapidly). The solvent is evaporated upon heating so as to form the transparent conductive layer 101.

Then, a carrier transport layer 102 may be optionally formed on the transparent conductive layer 101 by a method similar to that used to form the transparent conductive layer 101. Then, an organic light emitting layer is formed on the transparent conductive layer 101 (or on the transparent conductive layer 101 and the carrier transport layer 102). For example, an organic light emitting material source may be provided in the tube body 100. Then, an organic light emitting layer is evaporated or deposited on the transparent conductive layer 101 by using the organic light emitting material source.

The embodiment of FIG. 3A is described as an example. The organic light emitting material source in the tube body 100 may be an organic light emitting material 304 coated on a bulk body 30. Then, the organic light emitting material 304 is evaporated to a gas 304′ upon heating and coated onto the transparent conductive layer 101 to form an organic light emitting layer 104, as shown in FIG. 3B. Then, the bulk body 30 may be removed out, and then a carrier transport layer and a conductive layer may be optionally formed on the organic light emitting layer 104 so as to complete the light emitting device 10, as shown in FIG. 2.

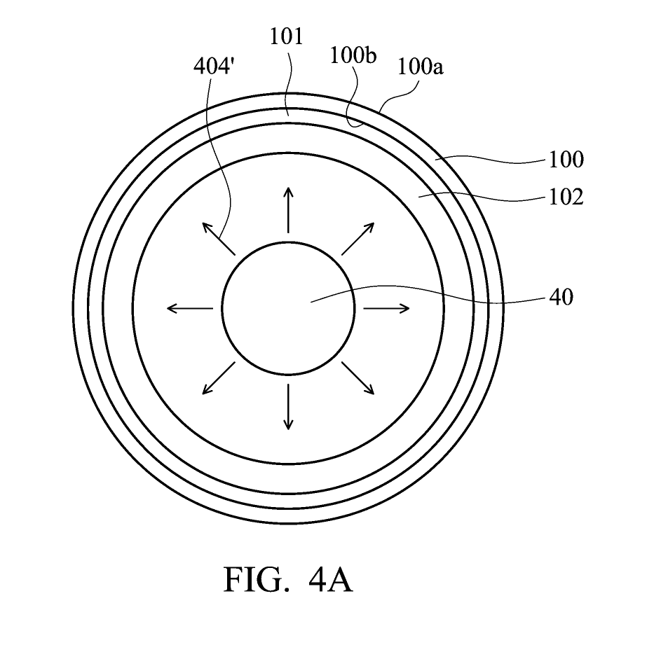

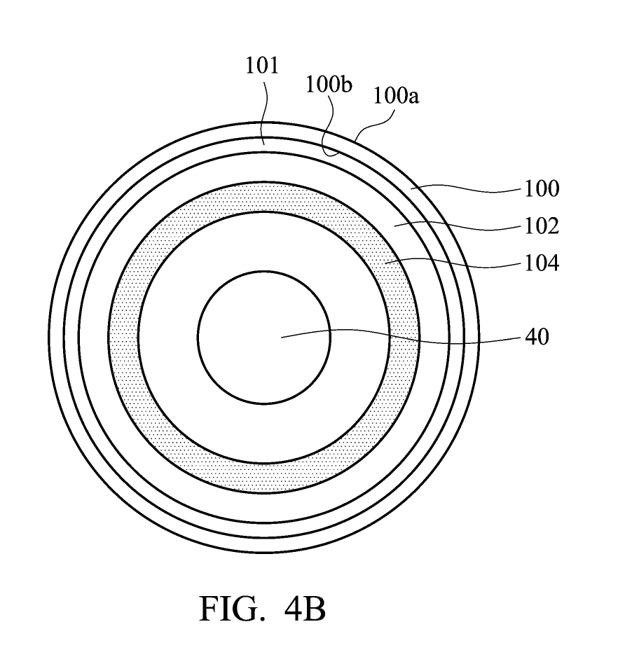

It should be noted that, the forming method of the light emitting device of the embodiments of the present disclosure is not limited to the above methods. FIGS. 4A-4B are cross-sectional views of a process for a light emitting device according to another embodiment of the present disclosure, and the same or similar reference numbers are used to represent the same or similar elements.

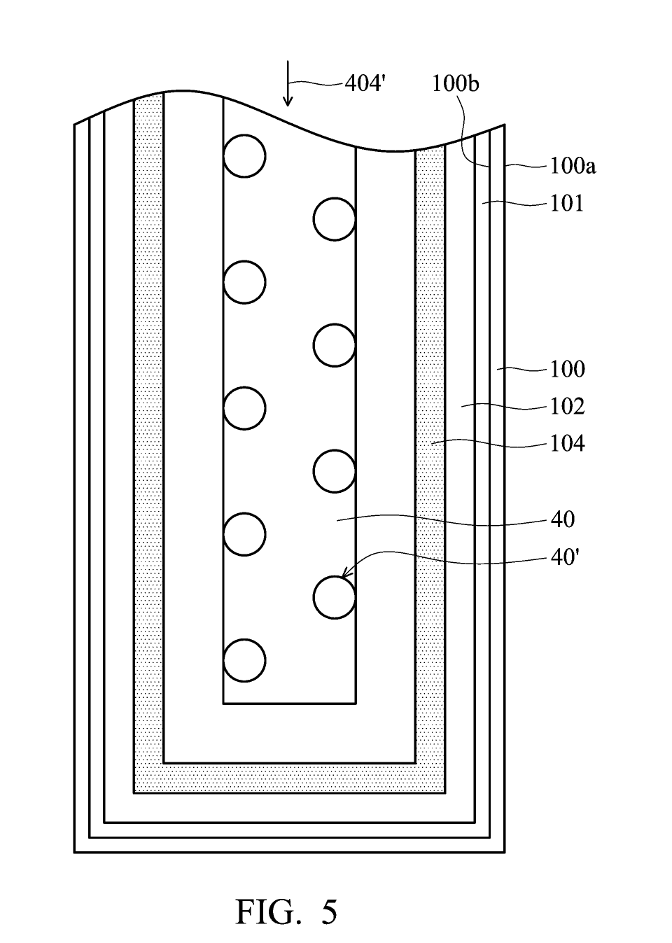

As shown in FIG. 4A, in the present embodiment, the organic light emitting material source in the tube body 100 may be an organic light emitting material gas. FIG. 5 is a cross-sectional view of the structure of FIG. 4A in another direction (i.e. longitudinal direction). Referring to FIGS. 5 and 4A, a gas guide tube 40 with at least one hole 40′ may be inserted into the tube body 100. Then, an organic light emitting material gas 404′ for forming the organic light emitting layer may be injected into the gas guide tube 40. As shown in FIG. 4B, the organic light emitting material gas 404′ may be injected into the tube body 100 through the hole 40′ of the gas guide tube 40 to form the organic light emitting layer 104 on the transparent conductive layer 101. Then, the gas guide tube 40 may be removed out, and then a carrier transport layer and a conductive layer may be optionally formed on the organic light emitting layer 104 so as to complete the light emitting device 10, as shown in FIG. 2.

It should be noted that, the forming method of the light emitting device of the embodiments of the present disclosure is not limited to the above methods. In another embodiment, the organic light emitting material source in the tube body 100 may be an organic light emitting material solution. For example, the material for forming the organic light emitting layer may be dissolved in a solvent, or the material for forming the organic light emitting layer may be a liquid per se at ambient temperature. Then, a suitable amount of the organic light emitting material solution may be dropped in the tube body 100, and then the organic light emitting material solution is coated on the transparent conductive layer 101 by spin coating to form the organic light emitting layer 104. Then, a carrier transport layer and a conductive layer may be optionally formed on the organic light emitting layer 104 so as to complete the light emitting device 10, as shown in FIG. 2.

Through the methods of the above embodiments, each material stacking layer of the organic light emitting diode may be annularly stacked in the lamp tube to form an organic light emitting device with a shape which is substantially the same as the existing lamp tubes or lamp bulbs. The light emitting device of the embodiments of the present disclosure may directly replace existing lamp tubes for illumination, without need to redesign lamp holders or other equipment. The light emitting device of the embodiments of the present disclosure eliminates the need for using mercury vapor, so the light emitting device of the embodiments of the present disclosure is an illuminating device which is more safe, environmentally friendly, and economical.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light emitting device, comprising:
an inflexible tube comprising an external surface and an internal surface;
a transparent conductive layer on the internal surface of the inflexible tube;
an organic light emitting layer disposed in the inflexible tube and on the transparent conductive layer; and
a conductive layer disposed in the inflexible tube and on the organic light emitting layer.

2. The organic light emitting device as claimed in claim 1, wherein the inflexible tube has a flexural strength larger than 200 Kg/cm².

3. The organic light emitting device as claimed in claim 1, further comprising:
a first carrier transport layer between the transparent conductive layer and the organic light emitting layer.

4. The organic light emitting device as claimed in claim 1, further comprising:
a second carrier transport layer between the conductive layer and the organic light emitting layer.

5. The organic light emitting device as claimed in claim 1, further comprising:
a first electrode electrically connecting the transparent conductive layer; and
a second electrode electrically connecting the transparent conductive layer.

6. The organic light emitting device as claimed in claim 1, wherein the inflexible tube comprises a cylindrical tube, a spiral tube, a spherical tube, an elliptical tube, a tapered tube, a rectangular tube, or combinations thereof.

7. The organic light emitting device as claimed in claim 1, wherein the internal surface of the inflexible tube is a nonplanar curved surface.

8. The organic light emitting device as claimed in claim 1, wherein the organic light emitting layer comprises a stacking structure comprising a plurality of light emitting layers.

9. A method for forming an organic light emitting device, comprising:
providing a tube body comprising an external surface and an internal surface;
forming a transparent conductive layer on the internal surface of the tube body;
providing an organic light emitting material source in the tube body;
evaporating or depositing an organic light emitting layer on the transparent conductive layer by using the organic light emitting material source; and
forming a conductive layer on the organic light emitting layer in the tube body.

10. The method for forming the organic light emitting device as claimed in claim 9, wherein the step of providing the organic light emitting material source comprises:
disposing a bulk body in the tube body, wherein an organic light emitting material is coated on a surface of the bulk body; and
heating the organic light emitting material such that a portion of the organic light emitting material is evaporated onto the transparent conductive layer to form the organic light emitting layer.

11. The method for forming the organic light emitting device as claimed in claim 9, wherein the step of providing the organic light emitting material source comprises:
providing an organic light emitting material gas in the tube body; and
depositing the organic light emitting material gas onto the transparent conductive layer to form the organic light emitting layer.

12. The method for forming the organic light emitting device as claimed in claim 9, wherein the step of providing the organic light emitting material source comprises:
providing an organic light emitting material solution in the tube body; and
spin coating the organic light emitting material solution onto the transparent conductive layer to form the organic light emitting layer.
